(19) United States
(12) Patent Application Publication
(10) Pub. No.: US 2024/0139903 A1
(43) Pub. Date: May 2, 2024

(54) POLISHING PAD AND METHOD FOR MANUFACTURING POLISHING PAD

(71) Applicant: FUJIBO HOLDINGS, INC., Tokyo (JP)

(72) Inventors: Teppei TATENO, Ehime (JP); Hiroshi KURIHARA, Ehime (JP); Satsuki YAMAGUCHI, Ehime (JP); Yamato TAKAMIZAWA, Ehime (JP)

(73) Assignee: FUJIBO HOLDINGS, INC., Tokyo (JP)

(21) Appl. No.: 18/278,838

(22) PCT Filed: Mar. 23, 2022
(86) PCT No.: PCT/JP2022/013510

§ 371 Date: Aug. 24, 2023

(30) Foreign Application Priority Data
Mar. 30, 2021 (JP) 2021-056759

(51) Int. Cl. B24B 37/24; B24D 3/00

(52) U.S. Cl. CPC B24B 37/24; B24D 3/00

(57) ABSTRACT

A polishing pad comprising a polishing layer that has a polishing surface for performing a polishing process on an item to be polished, wherein the polishing layer includes hollow microspheres that form hollow bodies within the polishing layer, a cross-section of the polishing layer has an average pore diameter of 10-14 μm, and in a histogram of pore diameters in a cross-section of the polishing layer where the bin width is 1 μm, the sum of pores that are 25 μm or greater is 5% or less with respect to the total number of pores in the cross-section, and the sum of the areas of the pores in each bin that is 25 μm or greater is 20% or less with respect to the total area of the pores in the cross-section.

### TECHNICAL FIELD

The present invention relates to a polishing pad. In detail, the present invention relates to a polishing pad that can be suitably used to polish optical materials, semiconductor wafers, semiconductor devices, hard disk substrates and the like.

### BACKGROUND ART

As a polishing method for flattening the surfaces of optical materials, semiconductor wafers, semiconductor devices and hard disk substrates, a chemical mechanical polishing (CMP) method has been ordinarily used.

The CMP method will be described using FIG. 1. As shown in FIG. 1, a polishing device 1 configured to perform the CMP method is provided with a polishing pad 3, and the polishing pad 3 includes a polishing layer 4 that is a layer that comes into contact with an item to be polished 8 held with a holding surface plate 16 and performs polishing and a cushion layer 6 that supports the polishing layer 4. The polishing pad 3 is driven to rotate in a state where the item to be polished 8 is pressed and polishes the item to be polished 8. At that time, a slurry 9 is supplied between the polishing pad 3 and the item to be polished 8. The slurry 9 is a mixture (dispersion) of water and a variety of chemical components or fine hard abrasive grains and enhances the polishing effect due to a relative movement between the item to be polished 8 and the chemical components or the abrasive grains in the slurry that are made to flow. The slurry 9 is supplied to and discharged from a polishing surface through grooves or holes.

Incidentally, polishing pads that are used to polish semiconductor devices normally have a polishing layer formed of a synthetic resin such as polyurethane, and voids are formed in this polishing layer. These voids are open on the surface of the polishing layer, and thus the abrasive grains that are contained in the polishing slurry are held therein during polishing, whereby the polishing of an object to be polished progresses. A method in which hollow microspheres are incorporated into the resin is a conventionally well-known method for forming such voids. Recently, in order to realize more accurate polishing, studies have been underway to make hollow microspheres smaller in diameter or uniform.

Patent Literature 1 discloses a polishing pad containing unexpanded hollow microspheres having an average particle diameter of 20 μm or less and having a high density and an excellent polishing rate.

In addition, Patent Literature 2 discloses a polishing pad in which the use of a solid blowing agent such as hollow microspheres and a gas blowing agent such as an inert gas provides a wide pore distribution and makes it possible to adjust the polishing performance.

### CITATION LIST

### Patent Literature

[Patent Literature 1]

Japanese Patent Laid-Open No. 2019-069497
[Patent Literature 2]

Japanese Patent Laid-Open No. 2019-069507

### SUMMARY OF INVENTION

### Technical Problem

However, in the polishing pads described in Patent Literature 1 and Patent Literature 2, the proportion of pores that were 25 μm or greater was large in the distribution of pore diameters that were measured in a cross-section of the polishing layer, and there were cases where polishing debris or the like resided in the pores and made defect performance insufficient.

The present invention has been made in consideration of the above-described problems, and an objective of the present invention is to provide a polishing pad enabling both a favorable polishing rate and defect performance to be satisfied.

### Solution to Problem

As a result of intensive studies, the present inventors found a polishing pad in which both a favorable polishing rate and defect performance are satisfied by the use of predetermined hollow microspheres. That is, the present invention includes the followings.

[1] A polishing pad comprising a polishing layer that has a polishing surface for performing a polishing process on an item to be polished,
wherein the polishing layer includes hollow microspheres that form hollow bodies within the polishing layer,
a cross-section of the polishing layer has an average pore diameter of 10-14 μm,
in a histogram of pore diameters in the cross-section of the polishing layer where a bin width is 1 μm,
a sum of pores that are 25 μm or greater is 5% or less with respect to the total number of pores in the cross-section, and
a sum of areas of the pores in each bin that is 25 μm or greater is 20% or less with respect to a total area of the pores in the cross-section.

[2] The polishing pad according to [1], wherein a sum of the pores in each bin that is 30 μm or greater is 3% or less with respect to the total number of pores in the polishing surface, and a sum of areas of the pores in each bin that is 30 μm or greater is 10% or less with respect to a total area of the pores in the polishing surface.

[3] The polishing pad according to [1] or [2], wherein the hollow microspheres are derived from unexpanded hollow microspheres having a median diameter (D50) of 6 μm or less.

[4] A manufacturing method for manufacturing a polishing pad including a polishing layer that has a polishing surface for performing a polishing process on an item to be polished,
wherein the polishing layer includes hollow microspheres that form hollow bodies within the polishing layer,
a cross-section of the polishing layer has an average pore diameter of 10-14 μm,
in a histogram of pore diameters in the cross-section of the polishing layer where a bin width is 1 μm,
a sum of pores that are 25 μm or greater is 5% or less with respect to the total number of pores in the cross-section, and
a sum of areas of the pores in each bin that is 25 μm or greater is 20% or less with respect to a total area of the pores in the cross-section, and
the polishing layer is formed by mixing and reacting a urethane bond-containing polyisocyanate compound, a curing agent and unexpanded hollow microspheres having a median diameter (D50) of 6 μm or less.

[5] The manufacturing method according to [4], wherein the reaction is performed under a temperature control so as not to exceed a temperature of 140° C.

[6] A polishing method for polishing an item to be polished using a polishing pad and abrasive grains,
wherein the polishing pad includes a polishing layer that has a polishing surface for performing a polishing process on an item to be polished,
the polishing layer includes hollow microspheres that form hollow bodies within the polishing layer,
a cross-section of the polishing layer has an average pore diameter of 10-14 μm,
in a histogram of pore diameters in the cross-section of the polishing layer where a bin width is 1 μm,
a sum of pores that are 25 μm or greater is 5% or less with respect to the total number of pores in the cross-section, and
a sum of areas of the pores in each bin that is 25 μm or greater is 20% or less with respect to a total area of the pores in the cross-section,
the abrasive grains have diameters of 0.01-0.2 μm, and
polishing is performed by bringing the item to be polished into contact with the polishing surface of the polishing pad in the presence of the abrasive grains and rotating any one or both of the polishing pad and the polishing item to be polished.

### Advantageous Effects of Invention

A polishing pad including a polishing layer containing predetermined hollow microspheres brings a favorable polishing rate and has excellent defect performance.

### BRIEF DESCRIPTION OF DRAWINGS

FIG. 1 is a perspective view of a polishing device 1.

FIG. 2 is a cross-sectional view of a polishing pad.

FIG. 3 is enlarged photographs of polishing layers of polishing pads and histograms of pore diameters in Example 1 and Comparative Example 1.

FIG. 4 is enlarged photographs of polishing layers of polishing pads and histograms of pore diameters in Example 2 and Comparative Example 2.

FIG. 5a shows changes in polishing rates when metallic copper films have been polished using the polishing pads of Examples 1 and 2 and Comparative Examples 1 and 2.

FIG. 5b is the numbers of defects when the metallic copper films have been polished using Examples 1 and 2 and Comparative Examples 1 and 2.

FIG. 6a shows changes in polishing rates when silicon oxide films have been polished using the polishing pads of Examples 1 and 2 and Comparative Examples 1 and 2.

FIG. 6b is the numbers of defects when the silicon oxide films have been polished using Examples 1 and 2 and Comparative Examples 1 and 2.

### DESCRIPTION OF EMBODIMENTS

Hereinafter, an embodiment of an invention will be described, but the present invention is not limited to the embodiment of the invention.

### <<Polishing Pad>>

A polishing pad of the present invention brings a favorable polishing rate and has excellent defect performance. In the present specification, “particle” means a fine particle that has been contained in a polishing slurry or the like and remains attached to the surface of an item to be polished, “pad debris” means debris of a polishing layer that is generated due to the wear of the surface of the polishing layer in the polishing pad during a polishing step and is attached to the surface of the item to be polished, and “scratch” means a mark formed on the surface of the item to be polished. In the present specification, “defect” refers to a collective term for defects including the above-described particle, pad debris, scratch and the like.

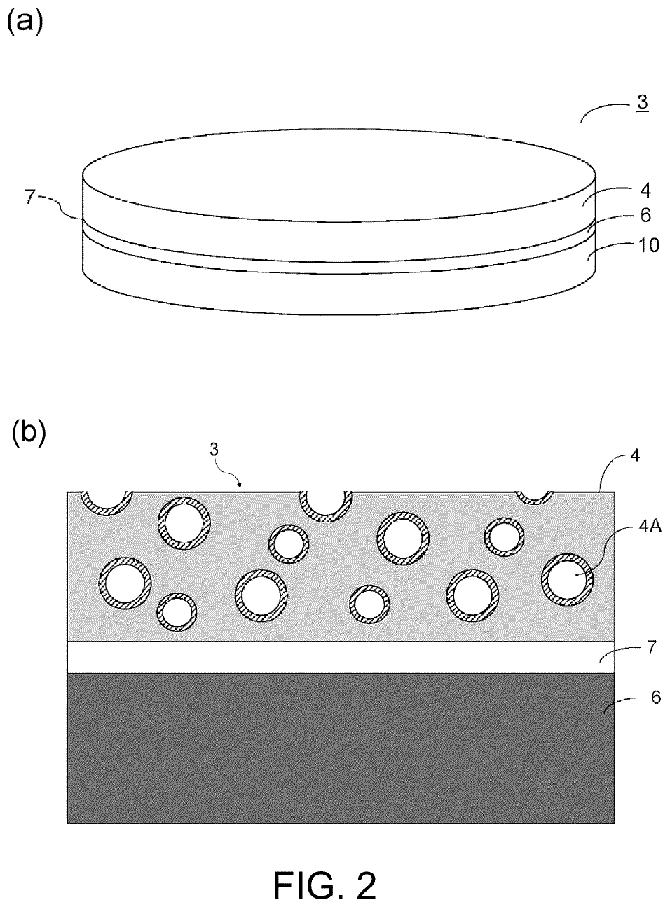

The structure of a polishing pad 3 will be described using FIG. 2(a). The polishing pad 3 includes a polishing layer 4 and a cushion layer 6 as shown in FIG. 2(a). The shape of the polishing pad 3 is preferably a disc shape, but is not particularly limited, and the size (diameter) can also be determined as appropriate depending on the size or the like of a polishing device 1 including the polishing pad 3 and can be set to, for example, approximately 10 cm to 2 m in diameter.

In the polishing pad 3 of the present invention, it is preferable that the polishing layer 4 adhere to the cushion layer 6 through an adhesive layer 7 as shown in FIG. 2(a).

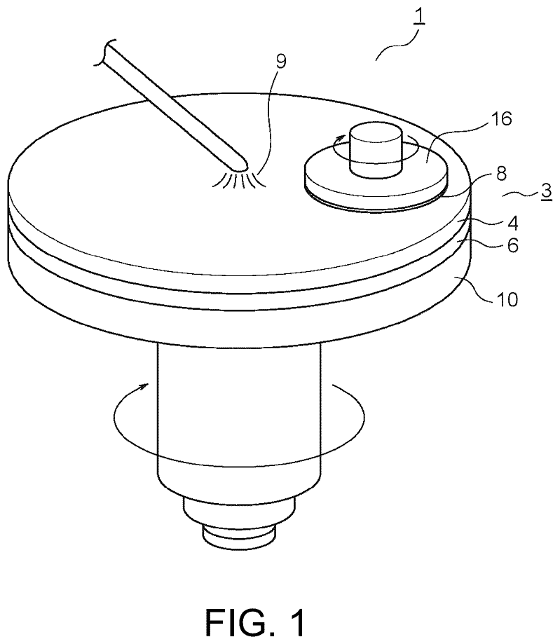

The polishing pad 3 is pasted to a polishing surface plate 10 of the polishing device 1 with double-sided tape or the like provided on the cushion layer 6. The polishing pad 3 is driven to rotate by the polishing device 1 in a state where the item to be polished 8 is pressed and polishes the item to be polished 8 (refer to FIG. 1).

### <Polishing Layer>

### (Configuration)

The polishing pad 3 includes the polishing layer 4 that is a layer for polishing the item to be polished 8. As a material that configures the polishing layer 4, a polyurethane resin, a polyurea resin and a polyurethane polyurea resin can be suitably used, and a polyurethane resin can be more preferably used.

The size (diameter) of the polishing layer 4 is the same as that of the polishing pad 3 and can be set to approximately 10 cm to 2 m in diameter, and the thickness of the polishing layer 4 can be set to normally approximately 1-5 mm.

The polishing layer 4 is rotated together with the polishing surface plate 10 of the polishing device 1 and polishes the item to be polished 8 by causing chemical components or abrasive grains that are contained in a slurry 9 to relatively move together with the item to be polished 8 while the slurry 9 is made to flow thereon.

The polishing layer 4 includes hollow microspheres 4A in a dispersed state. Since the hollow microspheres 4A are included in a dispersed state, once the polishing layer 4 is worn, the hollow microspheres 4A are exposed on a polishing surface, and fine voids are generated on the polishing surface. The slurry is held in these fine voids, whereby it is possible to further progress the polishing of the item to be polished 8.

The polishing layer 4 is formed by slicing a urethane resin foam obtained by casting and curing a liquid mixture in which a urethane bond-containing polyisocyanate compound (prepolymer) including the hollow microspheres 4A, which will be described below, and a curing agent (chain extender) have been mixed together. That is, the polishing layer 4 has been dry-molded.

### (Hollow Microspheres)

The hollow microspheres 4A that are included in the polishing layer 4 in the polishing pad of the present invention can be confirmed as hollow bodies on the polishing surface of the polishing layer 4 or a cross-section of the polishing layer 4. The hollow microspheres 4A that are included in the polishing layer 4 normally have diameters (or opening diameters) of 2-200 μm. Examples of the shape of the hollow microsphere 4A include a spherical shape, an elliptical shape and shapes close thereto.

In the polishing layer 4 of the present invention, the average pore diameter of pores on the cross-section or the polishing surface that are formed due to the hollow microspheres is 10-14 μm. When the average pore diameter is within this numerical range, it is possible to appropriately hold the slurry (or the abrasive grains that are contained in the slurry) and to achieve a favorable polishing rate. It is not realistic to set the average pore diameter to less than 10 μm since there is a problem in that special hollow microspheres need to be used or manufacturing or handling is difficult and the cost is taken. In addition, in a case where the average pore diameter is greater than 14 μm, there is a possibility that such pores may cause defect.

Furthermore, the pores on the cross-section or the polishing surface of the polishing layer 4 of the polishing pad of the present invention have a specific pore diameter distribution.

In order to express the pore diameter distribution, in the present specification, a histogram of pore diameters where a bin width is 1 μm is used. In the present specification, ranges of the measured pore diameters partitioned every 1 μm (for example, 20.0 μm or greater and less than 21.0 μm and the like) are regarded as the bins.

In the present invention, the sum of pores that are 25 μm or greater is 5% or less with respect to the total number of pores in the cross-section of the polishing layer. When the sum of the pores that are 25 μm or greater is 5% or less with respect to the total number of the pores in the cross-section, the number of the pores that are 25 μm or greater is small, and there is no bias in the number of openings, which is considered to affect the favorable defect performance. In addition, the sum of the pores in each bin that is 25 μm or greater is preferably 5% or less with respect to the total number of the pores in the cross-section of the polishing layer. The sum of the pores in each bin that is 25 μm or greater indicates that, in other words, the sum of pores that are 25 μm or greater and less than 26 μm is 5% or less with respect to the total number of the pores in the cross-section of the polishing layer, in addition, the sum of pores that are 26 μm or greater and less than 27 μm is also 5% or less with respect to the total number of the pores in the cross-section of the polishing layer and, furthermore, indicates that the same thing can be said regarding the number of pores in each bin that is 27 μm or greater. The sum of the pores in each bin that is 30 μm or greater is preferably 3% or less with respect to the total number of the pores in the cross-section.

In addition, in the present invention, the sum of the areas of the pores in each bin that is 25 μm or greater is 20% or less with respect to the total area of the pores in the cross-section.

When the sum of the areas of the pores in each bin that is 25 μm or greater is 20% or less with respect to the total area of the pores in the cross-section, the possibility of polishing debris or the like being held in the pores becomes low, which is also considered to affect the favorable defect performance. Regarding the pores that are 30 μm or greater for which the possibility of polishing debris or the like being held becomes higher, the sum of the areas of the pores in each bin that is 30 μm or greater is preferably 10% or less with respect to the total area of the pores in the cross-section.

As the hollow microspheres 4A, commercially available balloons can be used, and already-expanded balloons and unexpanded balloons can be used. The unexpanded balloons are thermal expandable microspheres and can be thermally expanded by heat.

In the present invention, when the urethane bond-containing polyisocyanate compound (prepolymer) and the curing agent, which form the polishing layer 4, are mixed together, unexpanded hollow microspheres are preferably mixed together. The use of the unexpanded hollow microspheres makes it possible to decrease the diameters (pore diameters) of the hollow microspheres 4A.

In the case of using the unexpanded hollow microspheres, since the reaction between the prepolymer and the curing agent is performed after the addition of the unexpanded hollow microspheres, the diameters tend to become larger than those of the unexpanded hollow microspheres due to reaction heat, and there are cases where the diameters become larger than assumed depending on temperatures. In order to suppress this, it is preferable to control the reaction temperature not to become too high and to prevent the reaction temperature from becoming a predetermined temperature or higher. While relying on a gas component that is contained in the unexpanded hollow microspheres, the reaction temperature is preferably 140° C. or lower and more preferably 100° C. or lower.

### (Grooving)

On the surface of the polishing layer 4 of the present invention on the item to be polished 8 side, it is possible to provide grooving. Grooves are not particularly limited and may be any of slurry discharge grooves that communicate with the circumference of the polishing layer 4 and slurry holding grooves that do not communicate with the circumference of the polishing layer 4, and both the slurry discharge grooves and the slurry holding grooves may be provided. Examples of the slurry discharge grooves include lattice grooves, radial grooves and the like, examples of the slurry holding grooves include concentric circular grooves, perforations (through-holes) and the like, and it is also possible to combine these.

### <Cushion Layer>

### (Configuration)

The polishing pad 3 of the present invention has the cushion layer 6. It is desirable that the cushion layer 6 make the contact of the polishing layer 4 with the item to be polished 8 more uniform. As a material of the cushion layer 6, the cushion layer may be composed of any of a flexible material such as an impregnated non-woven fabric impregnated with a resin, a synthetic resin or rubber, a foam having a bubble structure or the like. Examples thereof include resins such as polyurethane, polyethylene, polybutadiene and silicone, rubber such as natural rubber, nitrile rubber and polyurethane rubber, and the like. From the viewpoint of adjusting the density and the compressive elastic modulus, an impregnated non-woven fabric is preferable, and polyurethane is preferably used as a material that is used to impregnate the non-woven fabric.

In addition, as the cushion layer 6, a sponge-like polyurethane resin layer having microscopic bubbles is also preferably used.

The compressive elastic modulus, density and bubbles of the cushion layer 6 in the polishing pad 3 of the present invention are not particularly limited, and a cushion layer 6 having well-known characteristic values can be used.

### <Adhesive Layer>

The adhesive layer 7 is a layer for making the cushion layer 6 and the polishing layer 4 adhere to each other and is normally composed of double-sided tape or an adhesive. As the double-sided tape or adhesive, it is possible to use double-sided tape or an adhesive (for example, adhesive sheet) that is well-known in the related art.

The polishing layer 4 and the cushion layer 6 are pasted to each other with the adhesive layer 7. The adhesive layer 7 can be formed of at least one pressure-sensitive adhesive selected from an acrylic pressure-sensitive adhesive, an epoxy-based pressure-sensitive adhesive and a urethane-based pressure-sensitive adhesive. For example, it is possible to use an acrylic pressure-sensitive adhesive and to set the thickness to 0.1 mm.

### <<Method for Manufacturing Polishing Pad>>

A method for manufacturing the polishing pad 3 of the present invention will be described.

### <Material of Polishing Layer>

A material of the polishing layer 4 is not particularly limited; however, as the main component, a polyurethane resin, a polyurea resin and a polyurethane polyurea resin are preferable, and a polyurethane resin is more preferable. Examples of a specific material as the main component include materials that are obtained by reacting a urethane bond-containing polyisocyanate compound (prepolymer) and a curing agent.

Hereinafter, a method for manufacturing the material of the polishing layer 4 will be described using an example where a urethane bond-containing polyisocyanate compound and a curing agent are used.

A method for manufacturing the polishing layer 4 using a urethane bond-containing polyisocyanate compound and a curing agent is, for example, a manufacturing method including a material preparation step of preparing at least a urethane bond-containing polyisocyanate compound, an additive and a curing agent; a mixing step of mixing at least the urethane bond-containing polyisocyanate compound, the additive and the curing agent to obtain a liquid mixture for molding a compact; and a curing step of molding a polishing layer from the liquid mixture for molding a compact.

Hereinafter, the material preparation step, the mixing step and the molding step will be each described.

### <Material Preparation Step>

In order to manufacture the polishing layer 4 of the present invention, a urethane bond-containing polyisocyanate compound and a curing agent are prepared as the raw materials of a polyurethane resin compact (cured resin). Here, a urethane bond-containing polyisocyanate compound is a prepolymer (urethane prepolymer) for forming the polyurethane resin compact.

In a case where a polyurea resin compact or a polyurethane polyurea resin compact is used as the polishing layer 4, an appropriate prepolymer is used.

Hereinafter, each component will be described.

### (Urethane Bond-Containing Polyisocyanate Compound)

The urethane bond-containing polyisocyanate compound (urethane prepolymer) is a compound that is obtained by reacting a polyisocyanate compound and a polyol compound, which will be described below, under normally-used conditions and includes a urethane bond and an isocyanate group in the molecule. In addition, other components may be contained in the urethane bond-containing polyisocyanate compound to an extent that the effect of the present invention is not impaired.

As the urethane bond-containing polyisocyanate compound, a commercially available urethane bond-containing polyisocyanate compound may be used or a urethane bond-containing polyisocyanate compound synthesized by reacting a polyisocyanate compound and a polyol compound may be used. The reaction is not particularly limited, and an addition polymerization reaction may be performed using a method and conditions that are well-known in the manufacturing of polyurethane resins. For example, the urethane bond-containing polyisocyanate compound can be manufactured by a method in which a polyisocyanate compound heated to 50° C. is added to a polyol compound heated to 40° C. in a nitrogen atmosphere under stirring, after 30 minutes, the mixture is heated up to 80° C. and further reacted at 80° C. for 60 minutes.

### (Polyisocyanate Compound)

In the present specification, the polyisocyanate compound means a compound having two or more isocyanate groups in the molecule.

The polyisocyanate compound is not particularly limited as long as two or more isocyanate groups are present in the molecule. Examples of a diisocyanate compound having two isocyanate groups in the molecule include m-phenylene diisocyanate, p-phenylene diisocyanate, 2,6-tolylene diisocyanate (2,6-TDI), 2,4-tolylene diisocyanate (2,4-TDI), naphthalene-1,4-diisocyanate, diphenylmethane-4,4′-diisocyanate (MDI), 4,4′-methylene-bis(cyclohexyl isocyanate) (hydrogenated MDI), 3,3′-dimethoxy-4,4′-biphenyl diisocyanate, 3,3′-dimethyldiphenylmethane-4,4′-diisocyanate, xylylene-1,4-diisocyanate, 4,4′-diphenylpropane diisocyanate, trimethylene diisocyanate, hexamethylene diisocyanate, propylene-1,2-diisocyanate, butylene-1,2-diisocyanate, cyclohexylene-1,2-diisocyanate, cyclohexylene-1,4-diisocyanate, p-phenylene diisothiocyanate, xylylene-1,4-diisothiocyanate, ethylidine diisothiocyanate and the like. These polyisocyanate compounds may be used singly or a plurality of polyisocyanate compounds may be used in combination.

As the polyisocyanate compound, 2,4-TDI and/or 2,6-TDI is preferably contained.

### (Polyol Compound as Raw Material of Prepolymer)

In the present specification, the polyol compound means a compound having two or more hydroxyl groups (OH) in the molecule.

Examples of the polyol compound that is used to synthesize the urethane bond-containing polyisocyanate compound, which is the prepolymer, include diol compounds such as ethylene glycol, diethylene glycol (DEG) and butylene glycol, triol compounds and the like; and polyether polyol compounds such as poly(oxytetramethylene) glycol (or polytetramethylene ether glycol) (PTMG). Among these, PTMG is preferable. The number-average molecular weight of PTMG is preferably 500-2000, more preferably 600-1300 and still more preferably 650-1000.

The number-average molecular weight can be measured by gel permeation chromatography (GPC). In the case of measuring the number-average molecular weight (Mn) of the polyol compound from the polyurethane resin, it is also possible to estimate the number-average molecular weight by GPC after each component is decomposed by a normal method such as amine decomposition.

The polyol compounds may be used singly or a plurality of polyol compounds may be used in combination.

### (Additive)

As described above, as the material of the polishing layer 4, an additive, such as an oxidant, can be added as necessary.

### (Curing Agent)

In the method for manufacturing the polishing layer 4 of the present invention, a curing agent (also referred to as a chain extender) is mixed with the urethane bond-containing polyisocyanate compound or the like in the mixing step. When the curing agent is added, in a subsequent compact molding step, a main chain end of the urethane bond-containing polyisocyanate compound bonds to the curing agent to form a polymer chain, and the urethane bond-containing polyisocyanate compound cures.

Examples of the curing agent include polyvalent amine compounds such as ethylenediamine, propylenediamine, hexamethylenediamine, isophoronediamine, dicyclohexylmethane-4,4′-diamine, 3,3′-dichloro-4,4′-diaminodiphenylmethane (MOCA), 4-methyl-2,6-bis(methylthio)-1,3-benzenediamine, 2-methyl-4,6-bis(methylthio)-1,3-benzenediamine, 2,2-bis(3-amino-4-hydroxyphenyl)propane, 2,2-bis[3-(isopropylamino)-4-hydroxyphenyl]propane, 2,2-bis[3-(1-methylpropylamino)-4-hydroxyphenyl]propane, 2,2-bis[3-(1-methylpentylamino)-4-hydroxyphenyl] propane, 2,2-bis(3,5-diamino-4-hydroxyphenyl)propane, 2,6-diamino-4-methylphenol, trimethylethylene bis-4-aminobenzonate and polytetramethylene oxide-di-p-aminobenzonate; and polyvalent alcohol compounds such as ethylene glycol, propylene glycol, diethylene glycol, trimethylene glycol, tetraethylene glycol, triethylene glycol, dipropylene glycol, 1,4-butanediol, 1,3-butanediol, 2,3-butanediol, 1,2-butanediol, 3-methyl-1,2-butanediol, 1,2-pentanediol, 1,4-pentanediol, 2,4-pentanediol, 2,3-dimethyltrimethylene glycol, tetramethylene glycol, 3-methyl-4,3-pentanediol, 3-methyl-4,5-pentanediol, 2,2,4-trimethyl-1,3-pentanediol, 1,6-hexanediol, 1,5-hexanediol, 1,4-hexanediol, 2,5-hexanediol, 1,4-cyclohexanedimethanol, neopentyl glycol, glycerin, trimethylolpropane, trimethylolethane, trimethylolmethane, poly(oxytetramethylene) glycol, polyethylene glycol and polypropylene glycol. In addition, the polyvalent amine compounds may have a hydroxyl group, and examples of such amine-based compound include 2-hydroxyethylethylenediamine, 2-hydroxyethylpropylenediamine, hydroxyethylpropylenediamine, di-2-hydroxyethylethylenediamine, di-2-2-hydroxypropylethylenediamine, di-2-hydroxypropylethylenediamine and the like. As the polyvalent amine compounds, diamine compounds are preferable, and, for example, 3,3′-dichloro-4,4′-diaminodiphenylmethane (methylenebis-o-chloroaniline) (hereinafter, abbreviated as MOCA) is more preferably used.

The polishing layer 4 includes the hollow microspheres 4A each having an outer shell and being hollow inside. As described above, as a material of the hollow microspheres 4A, commercially available hollow microspheres can be used. Alternatively, hollow microspheres synthesized by a normal method and thus obtained may also be used. A material of the outer shell of the hollow microsphere 4A is not particularly limited, and examples thereof include polyvinyl alcohol, polyvinylpyrrolidone, poly(meth)acrylic acid, polyacrylamide, polyethylene glycol, polyhydroxy ether acrylate, maleic acid copolymers, polyethylene oxide, polyurethane, poly(meth)acrylonitrile, polyvinylidene chloride, polyvinyl chloride, organic silicone-based resins and copolymers obtained by combining two or more monomers that configure these resins. In addition, commercially available hollow microspheres are not limited to the followings, but examples thereof include EXPANCEL series (trade name manufactured by Akzo Nobel N.V.), MATSUMOTO MICROSPHERE (trade name manufactured by Matsumoto Yushi-Seiyaku Co., Ltd.) and the like.

The shape of the hollow microsphere 4A is not particularly limited and may be, for example, a spherical shape and a substantially spherical shape. As described above, unexpanded hollow microspheres are preferably used as a raw material.

In the polishing layer 4 to be obtained by the reaction, it is possible to arrange pores to be appropriate with the sizes of the hollow microspheres before being mixed with the resin. Particularly, unexpanded hollow microspheres are small compared with already-expanded hollow microspheres and are thus preferable. The average diameter of the unexpanded hollow microspheres to be used is preferably 2-20 μm and more preferably 5-10 μm. Still more preferably, unexpanded hollow microspheres having a median diameter (D50), at which the cumulative distribution of the hollow microspheres becomes 50%, of 6 μm or less are preferably used. The average particle diameter and the median diameter can be measured with a laser diffraction-type particle size distribution-measuring instrument (for example, MASTERSIZER 2000 manufactured by Spectris).

In addition, in the case of using specific commercially available hollow microspheres, it is possible to use hollow microspheres having sizes arranged within a desired range by classifying the hollow microspheres.

In the present invention, a classification method is not particularly limited, and it is possible to perform sieving, centrifugal air classification, dry air classification or the like.

The amount of the material of the hollow microspheres 4A added is preferably 0.1-10 parts by mass, more preferably 1-7 parts by mass and still more preferably 1-5 parts by mass with respect to 100 parts by mass of the urethane prepolymer.

In addition, apart from the above-described components, a blowing agent that has been conventionally used may be jointly used with the hollow microspheres 4A to an extent that the effect of the present invention is not impaired, and a non-reactive gas may be blown to each of the components in the mixing step. Examples of the blowing agent include, apart from water, blowing agents containing hydrocarbon having 5 or 6 carbon atoms as a main component.

Examples of the hydrocarbon include chain hydrocarbons such as n-pentane and n-hexane and alicyclic hydrocarbons such as cyclopentane and cyclohexane.

### <Mixing Step>

In the mixing step, the urethane bond-containing polyisocyanate compound (urethane prepolymer), the additive, the curing agent and the hollow microspheres obtained in the preparation step are supplied to a mixer and stirred and mixed together. The mixing step is performed in a state where the components have been heated to a temperature where the fluidity of each of the components can be secured; however, when the components are heated too much, the hollow microspheres expand and do not have a predetermined pore distribution, and thus caution needs to be taken.

### <Molding Step>

In the compact molding step, a liquid mixture for molding a compact prepared in the mixing step is made to flow into a rod-shaped formwork preheated to 30-100° C. and primarily cured, then, heated at approximately 100-150° C. for approximately 10 minutes to five hours to be secondarily cured, thereby molding a cured polyurethane resin (polyurethane resin compact). At this time, the urethane prepolymer and the curing agent react with each other to form a polyurethane resin, whereby the liquid mixture cures.

When the viscosity is too high, the fluidity becomes poor, and it becomes difficult to mix the urethane prepolymer substantially uniformly during mixing. When the viscosity is decreased by increasing the temperature, the pot life becomes short, conversely, mixed stains are generated, and a variation is caused in the sizes of hollow microspheres that are included in a foam to be obtained. Particularly, when the reaction temperature is too high, in a case where the unexpanded hollow microspheres are used, the hollow microspheres expand more than necessary, and it becomes impossible to obtain desired pores. On the contrary, when the viscosity is too low, bubbles move in the liquid mixture, and it becomes difficult to obtain a foam where the hollow microspheres have substantially evenly dispersed. Therefore, the viscosity of the prepolymer is preferably set within a range of 500-4000 mPa·s at a temperature of 50-80° C. Regarding this, the viscosity can be set by, for example, changing the molecular weight (degree of polymerization) of the prepolymer. The prepolymer is heated to approximately 50-80° C. and put into a flowable state.

In the molding step, the liquid mixture cast as necessary is reacted in the framework to form a foam. At this time, the prepolymer crosslink-cures by the reaction between the prepolymer and the curing agent.

After a compact is obtained, the compact is sliced in a sheet shape to form a plurality of polishing layers 4. For the slicing, an ordinary slicing machine can be used. During the slicing, the compact is sequentially sliced from the upper layer part to a predetermined thickness while the lower layer part of the compact is held. The thickness to be sliced is set, for example, within a range of 1.3-2.5 mm. In a foam molded with a 50 mm-thick framework, for example, approximately 10 mm parts in the upper layer part and the lower layer part of the foam cannot be used due to scratches or the like, and 10-25 polishing layers 4 are formed from the approximately 30 mm central part. A foam in which the hollow microspheres 4A have been substantially evenly formed is obtained in the curing molding step.

Grooving may be performed on a polishing surface of the obtained polishing layer 4 as necessary. In the present invention, a method for the grooving and the groove shape are not particularly limited.

In the polishing layer 4 thus obtained, after that, double-sided tape is pasted to a surface opposite to the polishing surface of the polishing layer 4. The double-sided tape is not particularly limited, and double-sided tape can be arbitrarily selected from double-sided tapes that are well-known in the related art and used.

### <Method for Manufacturing Cushion Layer 6>

The cushion layer 6 is preferably composed of an impregnated non-woven fabric impregnated with a resin. Preferable examples of the resin as a material of the impregnated non-woven fabric include polyurethanes such as polyurethane and polyurethane polyurea, acrylics such as polyacrylate and polyacrylonitrile, vinyls such as polyvinyl chloride, polyvinyl acetate and polyvinylidene fluoride, polysulfones such as polysulfone and polyethersulfone, acylated celluloses such as acetylated cellulose and butyrylated cellulose, polyamides, polystyrenes and the like. The density of the non-woven fabric before being impregnated with the resin (in a web state) is preferably 0.3 g/cm³ or less and more preferably 0.1-0.2 g/cm³. In addition, the density of the non-woven fabric after being impregnated with the resin is preferably 0.7 g/cm³ or less and more preferably 0.25-0.5 g/cm³. When the densities of the non-woven fabric before being impregnated with the resin and after being impregnated with the resin are the above-described upper limits or less, the processing accuracy improves. In addition, when the densities of the non-woven fabric before being impregnated with the resin and after being impregnated with the resin are the above-described lower limits or more, it is possible to reduce the permeation of the polishing slurry into a base material layer. The rate of the resin attached to the non-woven fabric is represented by the weight of the resin attached with respect to the weight of the non-woven fabric and is preferably 50 weight % or more and more preferably 75-200 weight %. When the rate of the resin attached to the non-woven fabric is the above-described upper limit or less, it is possible for the cushion layer to have desired cushioning properties.

### <Joining Step>

In a joining step, the formed polishing layer 4 and cushion layer 6 are pasted (joined) to each other with the adhesive layer 7. As the adhesive layer 7, for example, an acrylic pressure-sensitive adhesive is used, and the adhesive layer 7 is formed so as to be 0.1 mm in thickness. That is, the acrylic pressure-sensitive adhesive is applied onto the surface of the polishing layer 4 opposite to the polishing surface in a substantially uniform thickness. The surface of the polishing layer 4 opposite to the polishing surface P and the surface of the cushion layer 6 are pressed against each other across the applied pressure-sensitive adhesive, thereby pasting the polishing layer 4 and the cushion layer 6 to each other with the adhesive layer 7. In addition, the laminate is cut into a desired shape such as a circular shape, an inspection is performed to confirm whether or not dirt, foreign matters or the like are attached, and the polishing pad 3 is completed.

### <<Polishing>>

The polishing pad including the polishing layer containing the above-described predetermined hollow microspheres brings a favorable polishing rate and has excellent defect performance. Items to be polished for which the polishing pad of the present invention can be used are not particularly limited, and the polishing pad can be used for a variety of items to be polished such as metals and oxides. Preferable examples thereof include metallic copper, silicon oxides and the like.

How to set a polishing machine during polishing (the rotation speed of the polishing surface plate, the pressure, the time and the like) are not particularly limited and can be changed as appropriate depending on the status of items to be polished, other environments and the like.

In addition, during polishing, a slurry is used, and a slurry including abrasive grains may be used in the present invention. The kind of the abrasive grain is not particularly limited, and examples thereof include cerium oxide, zirconium oxide, zirconium silicate, cubic boron nitride (CBN), ferric oxide, manganese oxide, chromium oxide, silicon dioxide, alumina, barium carbonate, magnesium oxide, calcium carbonate, barium carbonate, magnesium oxide, mica and the like. In addition, since the polishing pad of the present invention has specific pores on the cross-section (that is, specific pores on the polishing surface), the abrasive grains preferably have a diameter of 0.01-0.2 μm.

### EXAMPLES

Hereinafter, the present invention will be described in more detail with examples, but the present invention is not limited to these examples.

In each of the examples and comparative examples, “parts” means “parts by mass” unless particularly otherwise described.

In addition, an NCO equivalent is a numerical value indicating the molecular weight of a prepolymer (PP) per NCO group that is obtained by “(the mass (parts) of a polyisocyanate compound+the mass (parts) of a polyol compound)/[(the number of functional groups per molecule of the polyisocyanate compound×the mass (parts) of the polyisocyanate compound/the molecular weight of the polyisocyanate compound)−(the number of functional groups per molecule of the polyol compound×the mass (parts) of the polyol compound/the molecular weight of the polyol compound)].”

### (Manufacturing of Polishing Layer A)

4.5 Parts of unexpanded hollow microspheres each having a shell part composed of an acrylonitrile-vinylidene chloride copolymer and containing an isobutane gas in the shell were added to and mixed with 100 parts of an isocyanate-terminated urethan prepolymer (urethane bond-containing polyisocyanate compound) having an NCO equivalent of 460 that had been formed by reacting 2,4-tolylene diisocyanate (TDI), poly(oxytetramethylene) glycol (PTMG) and diethylene glycol (DEG), thereby obtaining a liquid mixture. The obtained liquid mixture was charged into a first liquid tank and kept warm. Next, separately from a first liquid, 26.1 parts of MOCA was charged into a second liquid tank as a curing agent and kept warm in the second liquid tank. The respective liquids in the first liquid tank and the second liquid tank were injected into a mixer equipped with two inlets such that an R value, which indicates the equivalence ratio of an amino group and a hydroxyl group present in the curing agent with respect to a terminal isocyanate group in the prepolymer, reached 0.90. The two injected liquids were injected into a mold of a molding machine preheated to 80° C. while being mixed and stirred, then, the mold was clamped, and a molding was heated for 30 minutes and primarily cured. The primarily-cured molding was released from the mold and then secondarily cured in an oven at 120° C. for four hours, thereby obtaining a urethane molding. The obtained urethane molding was naturally cooled to 25° C., then, heated again in the oven at 120° C. for five hours and then sliced in a thickness of 1.3 mm, thereby obtaining a polishing layer A. Two kinds of polishing layers A were obtained using two kinds of hollow microspheres for comparison.

### (Manufacturing of Polishing Layer B)

A polishing layer B was produced by the same method for the polishing layer A except that 100 parts of an isocyanate-terminated urethan prepolymer (urethane bond-containing polyisocyanate compound) having an NCO equivalent of 420 was used as the first liquid, the liquid mixture, used to manufacture the polishing layer A and 28.8 parts of MOCA was used as the second liquid used to manufacture the polishing layer A. Since two kinds of hollow microspheres were used for comparison, two kinds of polishing layers B were obtained.

### <Manufacturing of Cushion Layer>

A non-woven fabric composed of polyester fibers was immersed in a urethane resin solution (manufactured by DIC Corporation, trade name “C1367”). After the immersion, the resin solution was squeezed using a mangle roller capable of pressurization between a pair of rollers to substantially uniformly impregnate the non-woven fabric with the resin solution. Next, the non-woven fabric was immersed in a coagulating liquid composed of water of room temperature to coagulate and regenerate the immersed resin, thereby obtaining a resin-impregnated non-woven fabric. After that, the resin-impregnated non-woven fabric was removed from the coagulating liquid, furthermore, immersed in a washing liquid composed of water to remove N,N-dimethylformamide (DMF) in the resin and then dried. After the drying, a skin layer on the surface was removed by a buffing treatment to produce a 1.3 mm-thick cushion layer.

### Examples and Comparative Examples

The polishing layer A or B and the cushion layer were joined with 0.1 mm-thick both-sided tape (tape including adhesive layers composed of an acrylic resin on both surfaces of a PET base material), thereby manufacturing a polishing pad of each of the examples and the comparative examples. The polishing layers A were used in Example 1 and Comparative Example 1, the polishing layers B were used in Example 2 and Comparative Example 2, and the same cushion layer was used as the cushion layer in all cases. In addition, as the hollow microspheres used, hollow microspheres each having a median diameter shown in Table 1 (hollow microspheres before being mixed with the resin, hollow microspheres classified by dry air classification in Examples 1 and 2, and unclassified hollow microspheres in Comparative Examples 1 and 2) were used to produce the polishing pads.

### (Density)

The densities (g/cm³) of the polishing layers were measured according to Japanese Industrial Standards (JIS K 6505).

(D hardness)

The D hardness of the polishing layers was measured using a D-type hardness meter according to Japanese Industrial Standards (JIS-K-6253). Here, a measurement sample was obtained by overlaying a plurality of the polishing layers as necessary so that the total thickness reached at least 4.5 mm or greater.

### (Pore Evaluation)

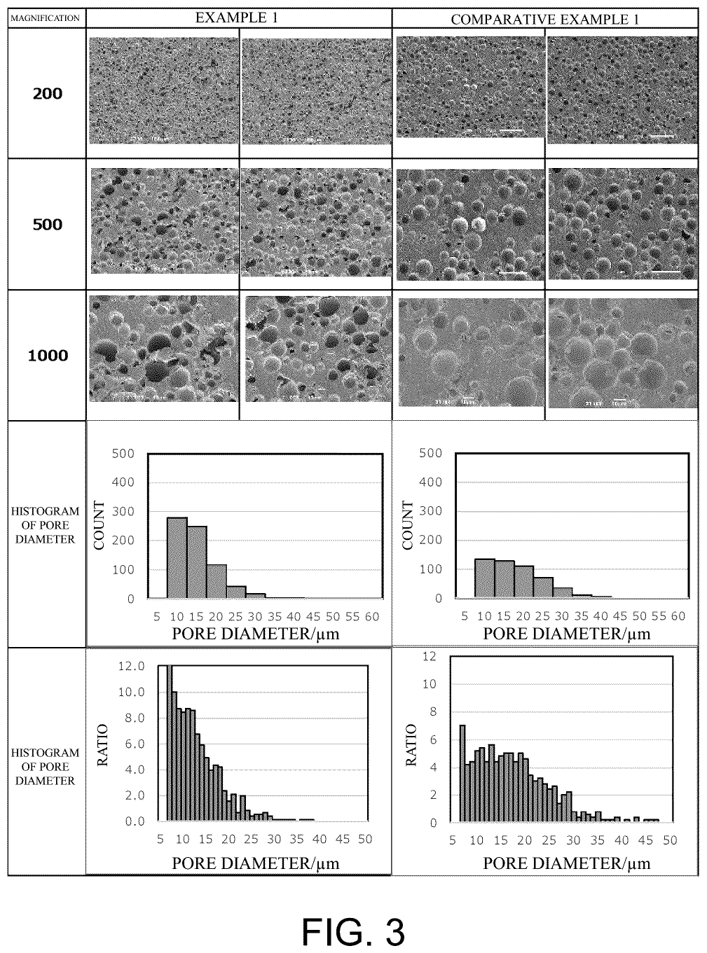

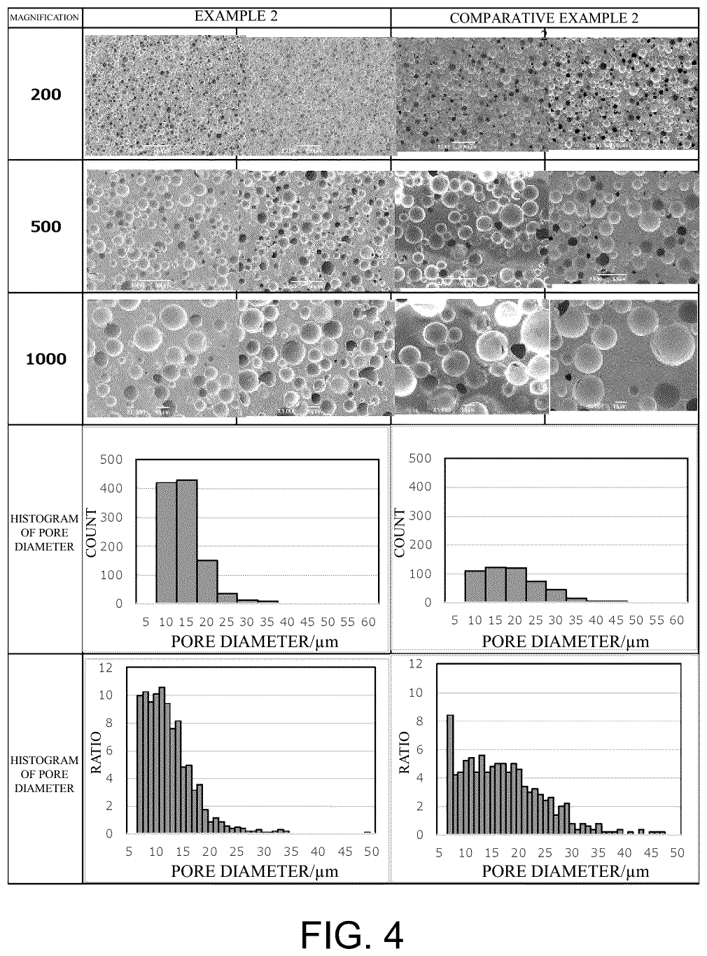

For the polishing layers obtained by slicing, the pore diameters of pores on cross-sections of the polishing layers, the porosities and the numbers of pores were investigated. Regarding the pore diameters, the porosities and the numbers of pores, 0.6 mm×0.6 mm ranges (excluding groove parts) on the surfaces of the polishing layers were observed at a magnification of 400 times with a laser microscope (VK-X1000, manufactured by Keyence Corporation), the obtained images were binarized with image processing software (WinROOF2018 Ver. 4.0.2, manufactured by Mitani Corporation), and the pores were confirmed. In addition, equivalent circle diameters and average values thereof (average pore diameters) were calculated from the areas of the individual pores. The pore diameters were shown using histograms of the pore diameters where the bin width was 1 μm (for example, 20.0 μm or greater and less than 21.0 μm and the like). The cutoff value (lower limit) of the pore diameters was set to 5 μm, and noise components were excluded. The results are shown in Table 1, FIG. 3 and FIG. 4. The pore diameter is the average value of the diameters of the pores shown in the laser microscopic image, the porosity is the proportion of an open area in a unit area (0.6 mm×0.6 mm), and the number of pores shows the number of pores in 0.6 mm×0.6 mm. In addition, the number and area proportions of 25 μm or greater show the number proportion and pore area proportion of pores that are 25 μm or greater in all pores. What has been described above is also true for the number and area proportions of 30 μm or greater.

TABLE 1

| | | Comparative | | Comparative |
|---|---|---|---|---|
| | Example 1 | Example 1 | Example 2 | Example 2 |
| Hollow microsphere* (before expansion) | D50 = 5.85 | D50 = 6.9 | D50 = 5.39 | D50 = 8.2 |
| | Over 10μ = 1.9% | | Over 10μ = 1.0% | |
| Polishing layer | A | A | B | B |
| Density/g/cm³ | 0.77 | 0.78 | 0.77 | 0.78 |
| D hardness/° | 55 | 56 | 63 | 62 |
| Pore diameter/μm | 12.7 | 13.9 | 12.0 | 16.3 |
| Porosity/% | 27.5 | 31.1 | 33.3 | 35.7 |
| Number of pores/pores | 711 | 630 | 908 | 515 |
| Number proportion of 25 μm or greater/% | 2.83 | 11.9 | 2.60 | 12.4 |
| Area proportion of 25 μm or greater/% | 12.7 | 33.7 | 14.2 | 35.5 |
| Number proportion of 30 μm or greater/% | 1.01 | 4.10 | 1.00 | 4.40 |
| Area proportion of 30 μm or greater/% | 6.01 | 15.3 | 7.70 | 17.3 |

*The values of the hollow microsphere are a characteristic before being mixed with the resin, D50 indicates the median diameter (50%), and Over 10μ indicates a proportion of 10 μm or greater.

As is clear from Table 1, while the physical properties, such as the density or the D hardness, were almost the same in the combination of Example 1 and Comparative Example 1 and in the combination of Example 2 and Comparative Example 2 where the polishing layers of the same configuration resin were used, in Example 1 and Example 2 where the hollow microspheres having small median diameters before being mixed with the resin were used, compared with

Comparative Example 1 and Comparative Example 2, the average pore diameters in the polishing layers were small (12.7 μm in Example 1 and 12.0 μm in Example 2 while greater than 14 μm in the comparative examples), the number proportions of pores that were 25 μm or greater were 5% or less (2.83% in Example 1 and 2.60% in Example 2 while greater than 10% in both of the comparative examples), the area proportions were 20% or less (12.7% in Example 1 and 14.2% in Example 2 while greater than 20% in both of the comparative examples), the number proportions of pores that were 30 μm or greater were 3% or less (1.01% in Example 1 and 1.00% in Example 2 while greater than 3% in both of the comparative examples) and the area proportions were 10% or less (6.01% in Example 1 and 7.70% in Example 2 while greater than 10% in both of the comparative examples), which are small values.

In addition, as is clear from the cross-sectional photographs in FIG. 3 and FIG. 4, in Example 1 and Example 2, compared with Comparative Example 1 and Comparative Example 2, the pores were small but had uniform sizes. Furthermore, it is found from the histograms of FIG. 3 and FIG. 4 that, in Example 1 and Example 2, the distribution of large pore diameters was small (the sums of the pores that were 25 μm or greater are 5% or less with respect to the total numbers of pores in the cross-sections of the polishing layers, the sums of pores in each bin that was 25 μm or greater were 5% or less with respect to the total numbers of pores in the cross-sections of the polishing layers, and the sums of pores in each bin that was 30 μm or greater were 3% or less with respect to the total numbers of pores in the cross-sections of the polishing layers).

### (Polishing Performance Evaluation)

Metal film substrates and oxide film substrates were polished under the following polishing conditions using the obtained polishing pads of Examples 1 and 2 and Comparative Examples 1 and 2.

### (Polishing Conditions)

Polishing machine used: F-REX300X (manufactured by Ebara Corporation)

Disk: B25 (manufactured by 3M Company) and A188 (manufactured by 3M Company)

Abrasive temperature: 20° C.

Polishing surface plate rotation speed: 85 rpm

Polishing head rotation speed: 86 rpm

Polishing pressure: 3.5 psi

Polishing slurry (metal film): CSL-9044C (a liquid mixture of CSL-9044C undiluted solution and pure water in a weight ratio of 1:1 was used) (manufactured by Fujimi Corporation)

Polishing slurry (oxide film): PL6115 (a liquid mixture of PL6115 undiluted solution and pure water in a weight ratio of 1:1 was used)

Polishing slurry flow rate: 200 ml/min.

Polishing time: 60 sec.

Item to be polished (metal film): Cu film substrate

Item to be polished (oxide film): Tetra ethyl ortho silicate (TEOS)-attached silicon wafer

Pad break: 35 N 10 min.

Conditioning: Ex-situ, 35 N, 4 scan

(Polishing rate)

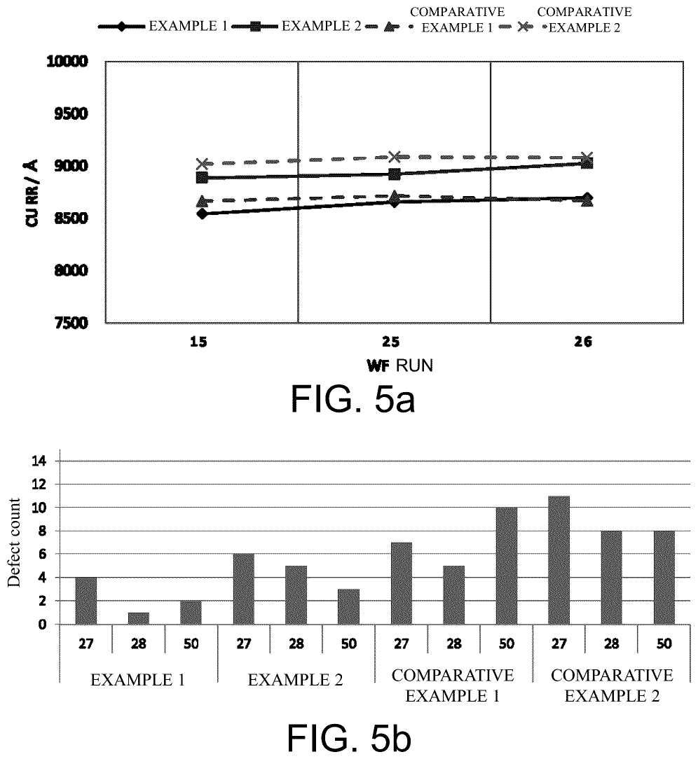

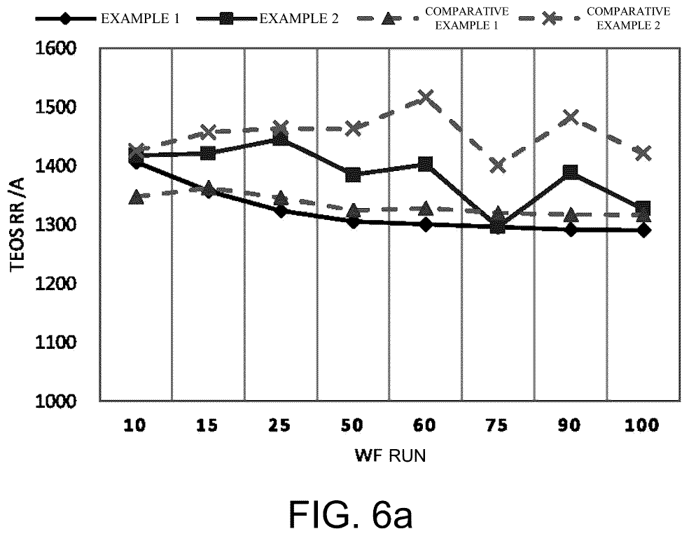

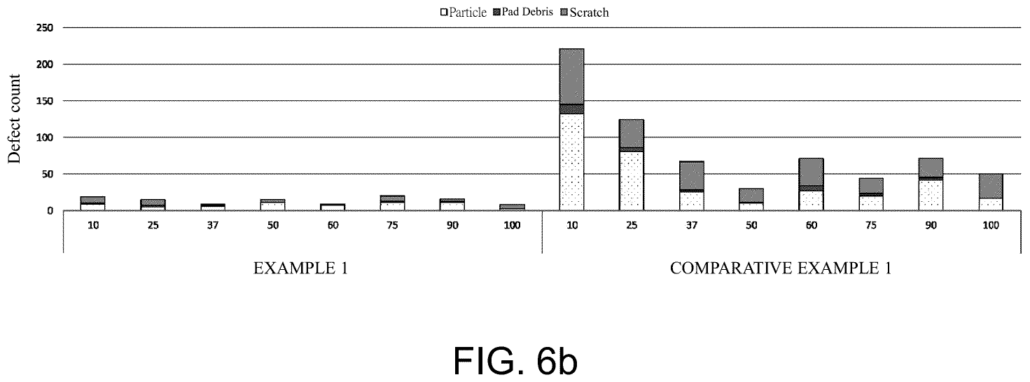

The polishing pad was installed at a predetermined position in a polishing device through double-sided tape having an acrylic adhesive, and a polishing process was performed under the above-described conditions. In addition, the polishing rate (unit: angstrom) was measured each time the number of substrates polished reached 15, 25 or 26 for the metal film substrates, and the polishing rate (unit: angstrom) was measured each time the number of substrates polished reached 10, 15, 25, 50, 60, 75, 90 or 100 for the oxide film substrates. The polishing results of the metal film substrates are shown in FIG. 5(a), and the polishing results of the oxide film substrates are shown in FIG. 6(a), respectively.

### (Defect)

Defects (surface defects) that were 90 nm or greater were detected using a high-sensitivity measurement mode of a surface inspection device (manufactured by KLA Corporation, SURF SCAN SP2XP) from each of the 27^{th}, 28^{th} and 50^{th} polished substrates regarding the metal film substrates and the 10^{th}, 25^{th}, 37^{th}, 50^{th}, 60^{th}, 75^{th}, 90^{th} and 100^{th} polished substrates regarding the oxide film substrates. Regarding each of the detected defects, analysis was performed on SEM images captured using a review SEM, and the number of defects classified into each of “particles”, “pad debris” and “scratch” was measured. The polishing results of the metal film substrates are shown in FIG. 5(b), and the polishing results of the oxide film substrates are shown in FIG. 6(b), respectively.

It can be said that, as the number of each defect of “particles”, “pad debris” and “scratch” becomes smaller, the defect becomes smaller and more favorable. In the polishing results of the metal film substrates, no differences were found between the examples and the comparative example regarding “particles” and “pad debris,” and the numbers of “scratches” are thus shown.

In addition, in the polishing results of the oxide film substrates, only the results of Example 1 and Comparative Example 1 are shown, but the same tendency was shown in Example 2 and Comparative Example 2.

As is clear from the polishing results of FIG. 5 and FIG. 6, in all of the metal film polishing and the oxide film polishing, the polishing pads of Example 1 and Example 2 showed the same polishing rates as those of Comparative Example 1 and Comparative Example 2 showing the same physical properties; however, regarding the defect, the numbers of each defect were small compared with those of the comparative examples. Particularly, it is found that “scratch” in the metal film substrates and the oxide film substrates and “particles” and “pad debris” in the oxide film substrates significantly decreased compared with those in the comparative examples.

### INDUSTRIAL APPLICABILITY

The present invention contributes to the manufacturing and sale of polishing pads and is thus industrially applicable.

### REFERENCE SIGNS LIST

1 Polishing device
3 Polishing pad
4 Polishing layer
4A Hollow microsphere
6 Cushion layer
7 Adhesive layer
8 Item to be polished
9 Slurry
10 Polishing surface plate

1. A polishing pad comprising:
a polishing layer that has a polishing surface for performing a polishing process on an item to be polished,
wherein the polishing layer includes hollow microspheres that form hollow bodies within the polishing layer,
a cross-section of the polishing layer has an average pore diameter of 10-14 μm,
in a histogram of pore diameters in the cross-section of the polishing layer where a bin width is 1 μm,
a sum of pores that are 25 μm or greater is 5% or less with respect to the total number of pores in the cross-section, and
a sum of areas of the pores in each bin that is 25 μm or greater is 20% or less with respect to a total area of the pores in the cross-section.

2. The polishing pad according to claim 1,
wherein a sum of the pores in each bin that is 30 μm or greater is 3% or less with respect to the total number of pores in the polishing surface, and a sum of areas of the pores in each bin that is 30 μm or greater is 10% or less with respect to a total area of the pores in the polishing surface.

3. The polishing pad according to claim 1,
wherein the hollow microspheres are derived from unexpanded hollow microspheres having a median diameter (D50) of 6 μm or less.

4. A manufacturing method for manufacturing a polishing pad including a polishing layer that has a polishing surface for performing a polishing process on an item to be polished,
wherein the polishing layer includes hollow microspheres that form hollow bodies within the polishing layer,
a cross-section of the polishing layer has an average pore diameter of 10-14 μm, in a histogram of pore diameters in the cross-section of the polishing layer where a bin width is 1 μm,
a sum of pores that are 25 μm or greater is 5% or less with respect to the total number of pores in the cross-section, and
a sum of areas of the pores in each bin that is 25 μm or greater is 20% or less with respect to a total area of the pores in the cross-section, and
the polishing layer is formed by mixing and reacting a urethane bond-containing polyisocyanate compound, a curing agent and unexpanded hollow microspheres having a median diameter (D50) of 6 μm or less.

5. The manufacturing method according to claim 4,
wherein the reaction is performed under a temperature control so as not to exceed a temperature of 140° C.

6. A polishing method for polishing an item to be polished using a polishing pad and abrasive grains,
wherein the polishing pad includes a polishing layer that has a polishing surface for performing a polishing process on an item to be polished,
the polishing layer includes hollow microspheres that form hollow bodies within the polishing layer,
a cross-section of the polishing layer has an average pore diameter of 10-14 μm,
in a histogram of pore diameters in the cross-section of the polishing layer where a bin width is 1 μm,
a sum of pores that are 25 μm or greater is 5% or less with respect to the total number of pores in the cross-section, and
a sum of areas of the pores in each bin that is 25 μm or greater is 20% or less with respect to a total area of the pores in the cross-section,
the abrasive grains have diameters of 0.01-0.2 μm, and
polishing is performed by bringing the item to be polished into contact with the polishing surface of the polishing pad in the presence of the abrasive grains and rotating any one or both of the polishing pad and the polishing item to be polished.
